(19) United States
(12) Patent Application Publication
(10) Pub. No.: US 2022/0084787 A1
(43) Pub. Date: Mar. 17, 2022

(54) PLASMA PROCESSING APPARATUS AND PLASMA PROCESSING METHOD

(71) Applicant: Tokyo Electron Limited, Tokyo (JP)

(72) Inventors: Chishio KOSHIMIZU, Kurokawa-gun, Miyagi (JP); Shinji KUBOTA, Kurokawa-gun, Miyagi (JP)

(73) Assignee: Tokyo Electron Limited, Tokyo (JP)

(21) Appl. No.: 17/421,001

(22) PCT Filed: Dec. 17, 2019
(86) PCT No.: PCT/JP2019/049499

§ 371 Date: Jul. 6, 2021

(30) Foreign Application Priority Data
Jan. 9, 2019 (JP) 2019-001662
Feb. 5, 2019 (JP) 2019-018833

(51) Int. Cl. H01J 37/32

(52) U.S. Cl. CPC H01J 37/32146

(57) ABSTRACT

In a plasma processing according to an exemplary embodiment, a pulsed negative direct-current voltage is periodically applied to the lower electrode. A frequency defining a cycle at which the pulsed negative direct-current voltage is periodically applied to the lower electrode is lower than a frequency of radio frequency power which is supplied to generate plasma. The radio frequency power is supplied in a first partial period in the cycle. A power level of the radio frequency power in a second partial period in the cycle is set to a power level reduced from a power level of the radio frequency power in the first partial period.

### TECHNICAL FIELD

Exemplary embodiments of the present disclosure relate to a plasma processing apparatus and a plasma processing method.

### BACKGROUND ART

A plasma processing apparatus is used in plasma processing on a substrate. The following Patent Literature 1 discloses a type of plasma processing apparatus. The plasma processing apparatus disclosed in Patent Literature 1 is provided with a chamber, an electrode, a radio frequency power source, and a radio frequency bias power source. The electrode is provided in the chamber. A substrate is placed on the electrode. The radio frequency power source supplies a pulse of radio frequency power in order to form a radio frequency electric field in the chamber. The radio frequency bias power source supplies a pulse of radio frequency bias power to the electrode.

### CITATION LIST

### Patent Literature

[Patent Literature 1] Japanese Unexamined Patent Publication No. H10-64915

### SUMMARY OF INVENTION

### Technical Problem

The present disclosure provides a technique for controlling an energy of ions that are supplied from plasma to a substrate.

### Solution to Problem

A plasma processing apparatus is provided in an exemplary embodiment. The plasma processing apparatus is provided with a chamber, a substrate support, a radio frequency power source, a bias power source, and a controller. The substrate support includes a lower electrode and an electrostatic chuck. The electrostatic chuck is provided on the lower electrode. The substrate support is configured to support a substrate which is placed thereon in the chamber. The radio frequency power source is configured to generate radio frequency power which is supplied to generate plasma from a gas in the chamber. The radio frequency power has a first frequency. The bias power source is electrically connected to the lower electrode. The bias power source is configured to periodically apply a pulsed negative direct-current voltage to the lower electrode at a cycle that is defined by a second frequency. The second frequency is lower than the first frequency. The controller is configured to control the radio frequency power source. The controller controls the radio frequency power source to supply the radio frequency power in a first partial period in the cycle. The controller controls the radio frequency power source to set a power level of the radio frequency power in a second partial period in the cycle to a power level reduced from a power level of the radio frequency power in the first partial period.

### Advantageous Effects of Invention

According to an exemplary embodiment, a technique for controlling an energy of ions that are supplied from plasma to a substrate is provided.

### BRIEF DESCRIPTION OF DRAWINGS

FIG. 1 is a diagram schematically showing a plasma processing apparatus according to an exemplary embodiment.

FIG. 2 is a timing chart of radio frequency power and a pulsed negative direct-current voltage according to an example.

FIG. 3 is a timing chart of radio frequency power and a pulsed negative direct-current voltage according to another example.

FIG. 4 is a timing chart of a pulsed negative direct-current voltage according to still another example.

FIG. 5 is a timing chart of radio frequency power according to still another example.

FIG. 6 is a timing chart of radio frequency power and a pulsed negative direct-current voltage according to still yet another example.

FIG. 7 is a timing chart of radio frequency power and a pulsed negative direct-current voltage according to further example.

FIGS. 8A and 8B are timing charts of pulsed negative direct-current voltages according to still further examples.

FIG. 9 is a flow chart showing a plasma processing method according to an exemplary embodiment.

### DESCRIPTION OF EMBODIMENTS

Hereinafter, various exemplary embodiments will be described.

A plasma processing apparatus is provided in an exemplary embodiment. The plasma processing apparatus is provided with a chamber, a substrate support, a radio frequency power source, a bias power source, and a controller. The substrate support includes a lower electrode and an electrostatic chuck. The electrostatic chuck is provided on the lower electrode. The substrate support is configured to support a substrate which is placed thereon in the chamber. The radio frequency power source is configured to generate radio frequency power which is supplied to generate plasma from a gas in the chamber. The radio frequency power has a first frequency. The bias power source is electrically connected to the lower electrode. The bias power source is configured to periodically apply a pulsed negative direct-current voltage to the lower electrode at a cycle that is defined by a second frequency. The second frequency is lower than the first frequency. The controller is configured to control the radio frequency power source. The controller controls the radio frequency power source to supply the radio frequency power in a first partial period in the cycle. The controller controls the radio frequency power source to set a power level of the radio frequency power in a second partial period in the cycle to a power level reduced from a power level of the radio frequency power in the first partial period.

In the above embodiment, the pulsed negative direct-current voltage is periodically supplied to the lower electrode at the cycle (hereinafter, referred to as a “pulse cycle”) that is defined by the second frequency. In the pulse cycle, the potential of the substrate fluctuates. In the first partial period in the pulse cycle, the radio frequency power having a power level higher than the power level of the radio frequency power in the second partial period in the pulse cycle is supplied. Therefore, the energy of ions that are supplied to the substrate depends on the setting of a time range of each of the first partial period and the second partial period within the pulse cycle. Therefore, according to the above embodiment, it becomes possible to control the energy of ions that are supplied from plasma to the substrate.

In an exemplary embodiment, the first partial period may be a period in which the pulsed negative direct-current voltage is applied to the lower electrode. The second partial period may be a period in which the pulsed negative direct-current voltage is not applied to the lower electrode. According to this embodiment, ions having relatively high energy can be supplied to the substrate.

In an exemplary embodiment, the first partial period may be a period in which the pulsed negative direct-current voltage is not applied to the lower electrode. The second partial period may be a period in which the pulsed negative direct-current voltage is applied to the lower electrode. According to this embodiment, ions having relatively low energy can be supplied to the substrate.

In an exemplary embodiment, the controller may control the radio frequency power source to stop supply of the radio frequency power in the second partial period. That is, the controller controls the radio frequency power source to supply a pulse of the radio frequency power periodically at the pulse cycle.

In an exemplary embodiment, the controller may control the radio frequency power source to periodically supply a pulse of the radio frequency power in the first partial period.

In an exemplary embodiment, a frequency for defining a cycle at which the pulse of the radio frequency power is supplied in the first partial period may be equal to or more than twice the second frequency and equal to or less than 0.5 times the first frequency.

In another exemplary embodiment, a plasma processing method is provided. The plasma processing apparatus used in the plasma processing method includes a chamber, a substrate support, a radio frequency, and a bias power source. The substrate support includes a lower electrode and an electrostatic chuck. The electrostatic chuck is provided on the lower electrode. The substrate support is configured to support a substrate which is placed thereon in the chamber. The radio frequency power source is configured to generate radio frequency power which is supplied to generate a plasma from a gas in the chamber. The radio frequency power has a first frequency. The bias power source is electrically connected to the lower electrode. The plasma processing method is executed to perform plasma processing on a substrate in a state where the substrate is placed on the electrostatic chuck. The plasma processing method includes periodically applying a pulsed negative direct-current voltage from the bias power source to the lower electrode at a cycle (i.e. a pulse cycle) that is defined by a second frequency. The second frequency is lower than the first frequency. The plasma processing method further includes supplying the radio frequency power from the radio frequency power source in a first partial period in the cycle. The plasma processing method further includes setting a power level of the radio frequency power in a second partial period in the cycle to a power level reduced from a power level of the radio frequency power in the first partial period.

In an exemplary embodiment, the first partial period may be a period in which the pulsed negative direct-current voltage is applied to the lower electrode. The second partial period may be a period in which the pulsed negative direct-current voltage is not applied to the lower electrode.

In an exemplary embodiment, the first partial period may be a period in which the pulsed negative direct-current voltage is not applied to the lower electrode. The second partial period may be a period in which the pulsed negative direct-current voltage is applied to the lower electrode.

In an exemplary embodiment, supply of the radio frequency power may be stopped in the second partial period.

In an exemplary embodiment, a pulse of the radio frequency power may be periodically supplied from the radio frequency power source in the first partial period.

In an exemplary embodiment, a frequency for defining a cycle at which the pulse of the radio frequency power is supplied in the first partial period may be equal to or more than twice the second frequency and equal to or less than 0.5 times the first frequency.

In an exemplary embodiment, the plasma processing method may further include periodically applying the pulsed negative direct-current voltage from the bias power source to the lower electrode at the pulse cycle in a period in which plasma is present in the chamber. The period has a time length longer than a time length of the cycle that is defined by the second frequency. In the period, supply of the radio frequency power from the radio frequency power source is stopped.

In an exemplary embodiment, the plasma processing method may further include supplying the radio frequency power from the radio frequency power source in a period having a time length longer than a time length of the pulse cycle. In the period, application of the pulsed negative direct-current voltage from the bias power source to the lower electrode is stopped,

Hereinafter, various exemplary embodiments will be described in detail with reference to the drawings. In the drawings, the same or equivalent portions are denoted by the same reference symbols.

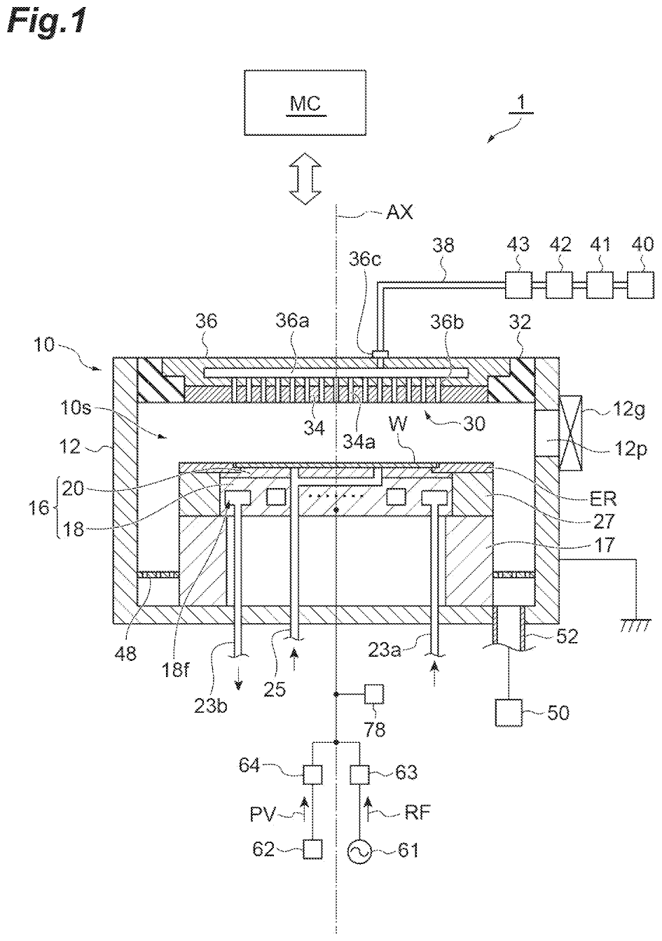

FIG. 1 is a diagram schematically showing a plasma processing apparatus according to an exemplary embodiment. A plasma processing apparatus 1 shown in FIG. 1 is a capacitively coupled plasma processing apparatus. The plasma processing apparatus 1 is provided with a chamber 10. The chamber 10 provides an internal space 10s therein. The central axis of the internal space 10s is an axis AX which extends in the vertical direction.

In an embodiment, the chamber 10 includes a chamber body 12. The chamber body 12 has a substantially cylindrical shape. The internal space 10s is provided in the chamber body 12. The chamber body 12 is formed of, for example, aluminum. The chamber body 12 is electrically grounded. A film having plasma resistance is formed on the inner wall surface of the chamber body 12, that is, the wall surface defining the internal space 10s. This film may be a film formed by anodization or a ceramic film such as a film formed of yttrium oxide.

A passage 12p is formed in a side wall of the chamber body 12. A substrate W passes through the passage 12p when it is transferred between the internal space 10s and the outside of the chamber 10. A gate valve 12g is provided along the side wall of the chamber body 12 for opening and closing of the passage 12p.

The plasma processing apparatus 1 is further provided with a substrate support 16. The substrate support 16 is configured to support the substrate W placed thereon in the chamber 10. The substrate W has a substantially disk shape. The substrate support 16 is supported by a support 17. The support 17 extends upward from a bottom portion of the chamber body 12. The support 17 has a substantially cylindrical shape. The support 17 is formed of an insulating material such as quartz.

The substrate support 16 has a lower electrode 18 and an electrostatic chuck 20. The lower electrode 18 and the electrostatic chuck 20 are provided in the chamber 10. The lower electrode 18 is formed of a conductive material such as aluminum and has a substantially disk shape.

A flow path 18f is formed in the lower electrode 18. The flow path 18f is a flow path for a heat exchange medium. As the heat exchange medium, a liquid refrigerant or a refrigerant (for example, chlorofluorocarbon) that cools the lower electrode 18 by vaporization thereof is used. A supply device for the heat exchange medium (for example, a chiller unit) is connected to the flow path 18f. The supply device is provided outside the chamber 10. The heat exchange medium is supplied from the supply device to the flow path 18f through a pipe 23a. The heat exchange medium supplied to the flow path 18f is returned to the supply device through a pipe 23b.

The electrostatic chuck 20 is provided on the lower electrode 18. The substrate W is placed on the electrostatic chuck 20 and held by the electrostatic chuck 20 when it is processed in the internal space 10s.

The electrostatic chuck 20 has a main body and an electrode. The main body of the electrostatic chuck 20 is formed of a dielectric such as aluminum oxide or aluminum nitride. The main body of the electrostatic chuck 20 has a substantially disk shape. The central axis of the electrostatic chuck 20 substantially coincides with the axis AX. The electrode of the electrostatic chuck 20 is provided in the main body. The electrode of the electrostatic chuck 20 has a film shape. A direct-current power source is electrically connected to the electrode of the electrostatic chuck 20 through a switch. When the voltage from the direct-current power source is applied to the electrode of the electrostatic chuck 20, an electrostatic attraction force is generated between the electrostatic chuck 20 and the substrate W. Due to the generated electrostatic attraction force, the substrate W is attracted to the electrostatic chuck 20 and held by the electrostatic chuck 20.

The electrostatic chuck 20 includes a substrate placing region. The substrate placing region is a region having a substantially disk shape. The central axis of the substrate placing region substantially coincides with the axis AX. The substrate W is placed on the upper surface of the substrate placing region when it is processed in the chamber 10.

In an exemplary embodiment, the electrostatic chuck 20 may further include an edge ring placing region. The edge ring placing region extends in a circumferential direction to surround the substrate placing region around the central axis of the electrostatic chuck 20. An edge ring ER is mounted on the upper surface of the edge ring placing region. The edge ring ER has a ring shape. The edge ring ER is placed on the edge ring placing region such that the central axis thereof coincides with the axis AX. The substrate W is disposed in a region surrounded by the edge ring ER. That is, the edge ring ER is disposed to surround the edge of the substrate W. The edge ring ER may have electrical conductivity. The edge ring ER is formed of, for example, silicon or silicon carbide. The edge ring ER may be formed of a dielectric such as quartz.

The plasma processing apparatus 1 may be further provided with a gas supply line 25. The gas supply line 25 supplies a heat transfer gas, for example, a He gas, from a gas supply mechanism to a gap between the upper surface of the electrostatic chuck 20 and the rear surface (lower surface) of the substrate W.

The plasma processing apparatus 1 may be further provided with an insulating region 27. The insulating region 27 is disposed on the support 17. The insulating region 27 is disposed outside the lower electrode 18 in a radial direction with respect to the axis AX. The insulating region 27 extends in the circumferential direction along the outer peripheral surface of the lower electrode 18. The insulating region 27 is formed of an insulator such as quartz. The edge ring ER is placed on the insulating region 27 and the edge ring placing region.

The plasma processing apparatus 1 is further provided with an upper electrode 30. The upper electrode 30 is provided above the substrate support 16. The upper electrode 30 closes an upper opening of the chamber body 12 together with a member 32. The member 32 has insulation properties. The upper electrode 30 is supported on an upper portion of the chamber body 12 through the member 32.

The upper electrode 30 includes a ceiling plate 34 and a support 36. The lower surface of the ceiling plate 34 defines the internal space 10s. A plurality of gas discharge holes 34a are formed in the ceiling plate 34. Each of the plurality of gas discharge holes 34a penetrates the ceiling plate 34 in a plate thickness direction (the vertical direction). Although being not limited, the ceiling plate 34 is formed of silicon, for example. Alternatively, the ceiling plate 34 may have a structure in which a plasma-resistant film is provided on the surface of a member made of aluminum. This film may be a film formed by anodization or a ceramic film such as a film formed of yttrium oxide.

The support 36 detachably supports the ceiling plate 34. The support 36 is formed of a conductive material such as aluminum, for example. A gas diffusion chamber 36a is provided in the interior of the support 36. A plurality of gas holes 36b extend downward from the gas diffusion chamber 36a. The plurality of gas holes 36b communicate with the plurality of gas discharge holes 34a, respectively. A gas introduction port 36c is formed in the support 36. The gas introduction port 36c is connected to the gas diffusion chamber 36a. A gas supply pipe 38 is connected to the gas introduction port 36c.

A gas source group 40 is connected to the gas supply pipe 38 through a valve group 41, a flow rate controller group 42, and a valve group 43. The gas source group 40, the valve group 41, the flow rate controller group 42, and the valve group 43 configure a gas supply unit. The gas source group 40 includes a plurality of gas sources. Each of the valve group 41 and the valve group 43 includes a plurality of valves (for example, on-off valves). The flow rate controller group 42 includes a plurality of flow rate controllers. Each of the plurality of flow rate controllers of the flow rate controller group 42 is a mass flow controller or a pressure control type flow rate controller. Each of the plurality of gas sources of the gas source group 40 is connected to the gas supply pipe 38 through a corresponding valve of the valve group 41, a corresponding flow rate controller of the flow rate controller group 42, and a corresponding valve of the valve group 43. The plasma processing apparatus 1 can supply gases from one or more gas sources selected from the plurality of gas sources of the gas source group 40 to the internal space 10s at individually adjusted flow rates.

A baffle plate 48 is provided between the substrate support 16 or the support 17 and the side wall of the chamber body 12. The baffle plate 48 may be configured, for example, by coating a member made of aluminum with ceramic such as yttrium oxide. A number of through-holes are formed in the baffle plate 48. An exhaust pipe 52 is connected to the bottom portion of the chamber body 12 below the baffle plate 48. An exhaust device 50 is connected to the exhaust pipe 52. The exhaust device 50 has a pressure controller such as an automatic pressure control valve, and a vacuum pump such as a turbo molecular pump, and is capable of reducing the pressure in the internal space 10s.

The plasma processing apparatus 1 is further provided with a radio frequency power source 61. The radio frequency power source 61 is a power source that generates radio frequency power RF. The radio frequency power RF is used to generate plasma from the gas in the chamber 10. The radio frequency power RF has a first frequency. The first frequency is a frequency in the range of 27 MHz to 100 MHz, for example, a frequency of 40 MHz or 60 MHz. The radio frequency power source 61 is connected to the lower electrode 18 through a matching circuit 63 in order to supply the radio frequency power RF to the lower electrode 18. The matching circuit 63 is configured to match the output impedance of the radio frequency power source 61 and the impedance on the load side (the lower electrode 18 side) with each other. The radio frequency power source 61 may not be electrically connected to the lower electrode 18 and may be connected to the upper electrode 30 through the matching circuit 63.

The plasma processing apparatus 1 is further provided with a bias power source 62. The bias power source 62 is electrically connected to the lower electrode 18. In an embodiment, the bias power source 62 is electrically connected to the lower electrode 18 through a low-pass filter 64. The bias power source 62 is configured to periodically apply a pulsed negative direct-current voltage PV to the lower electrode 18 at a cycle P_{P}, that is, a pulse cycle, which is defined by a second frequency. The second frequency is lower than the first frequency. The second frequency is, for example, 50 kHz or more and 27 MHz or less.

In a case where plasma processing is performed in the plasma processing apparatus 1, a gas is supplied to the internal space 10s. Then, the radio frequency power RF is supplied, whereby the gas is excited in the internal space 10s. As a result, plasma is generated in the internal space 10s. The substrate W supported by the substrate support 16 is processed by chemical species such as ions and radicals from the plasma. For example, the substrate is etched by the chemical species from the plasma. In the plasma processing apparatus 1, the pulsed negative direct-current voltage PV is applied to the lower electrode 18, whereby the ions from the plasma are accelerated toward the substrate W.

The plasma processing apparatus 1 is further provided with a controller MC. The controller MC is a computer which includes a processor, a storage device, an input device, a display device, and the like, and controls each part of the plasma processing apparatus 1. The controller MC executes a control program stored in the storage device and controls each part of the plasma processing apparatus 1, based on recipe data stored in the storage device. A process designated by the recipe data is executed in the plasma processing apparatus 1 under the control by the controller MC. A plasma processing method to be described later may be executed in the plasma processing apparatus 1 under the control of each part of the plasma processing apparatus 1 by the controller MC.

The controller MC controls the radio frequency power source 61 to supply the radio frequency power RF in at least a part of a first partial period P₁ in the cycle P_{P}. In the plasma processing apparatus 1, the radio frequency power RF is supplied to the lower electrode 18. Alternatively, the radio frequency power RF may be supplied to the upper electrode 30. The controller MC sets the power level of the radio frequency power RF in a second partial period P₂ in the cycle P_{P} to a power level reduced from the power level of the radio frequency power RF in the first partial period P₁. That is, the controller MC controls the radio frequency power source 61 to supply one or more pulses PRF of the radio frequency power RF in the first partial period P₁.

The power level of the radio frequency power RF in the second partial period P₂ may be 0 [W]. That is, the controller MC may control the radio frequency power source 61 to stop the supply of the radio frequency power RF in the second partial period P₂. Alternatively, the power level of the radio frequency power RF in the second partial period P₂ may be larger than 0 [W].

The controller MC is configured to provide a synchronization pulse, a delay time length, and a supply time length from the controller MC to the radio frequency power source 61. The synchronization pulse is synchronized with the pulsed negative direct-current voltage PV. The delay time length is a delay time length from the point in time of the start of the cycle P_{P} which is specified by the synchronization pulse. The supply time length is the length of a supply time of the radio frequency power HF. The radio frequency power source 61 supplies the one or more pulses PRF of the radio frequency power RF during the supply time length from a point in time delayed by the delay time length with respect to the point in time of the start of the cycle P_{P}. As a result, the radio frequency power RF is supplied to the lower electrode 18 in the first partial period P₁. The delay time length may be zero.

In an embodiment, the plasma processing apparatus 1 may be further provided with a voltage sensor 78. The voltage sensor 78 is configured to directly or indirectly measure the potential of the substrate W. In the example shown in FIG. 1, the voltage sensor 78 is configured to measure the potential of the lower electrode 18. Specifically, the voltage sensor 78 measures the potential of a power supply path connected between the lower electrode 18 and the bias power source 62.

The controller MC may determine, as the first partial period P₁, a period in which the potential of the substrate W measured by the voltage sensor 78 is higher or lower than an average value V_{AVE} of the potential of the substrate W in the cycle P_{P}. The controller MC may determine, as the second partial period P₂, a period in which the potential of the substrate W measured by the voltage sensor 78 is lower or higher than the average value V_{AVE}. The average value V_{AVE} of the potential of the substrate W may be a value determined in advance. The controller MC may control the radio frequency power source 61 to supply the radio frequency power RF as described above in the determined first partial period P₁. Further, the controller MC may control the radio frequency power source 61 to set the power level of the radio frequency power RF as described above in the determined second partial period P₂.

In the plasma processing apparatus 1, since the pulsed negative direct-current voltage PV is periodically supplied to the lower electrode 18 at the cycle P_{P}, the potential of the substrate W fluctuates within the cycle P_{P}. In the first partial period P₁ in the cycle P_{P}, the radio frequency power RF having a power level higher than the power level of the radio frequency power RF in the second partial period P₂ in the cycle P_{P} is supplied. Therefore, the energy of ions that are supplied to the substrate W depends on the setting of a time range of each of the first partial period P₁ and the second partial period P₂ in the cycle P_{P}. Therefore, according to the plasma processing apparatus 1, it becomes possible to control the energy of the ions that are supplied from plasma to the substrate W.

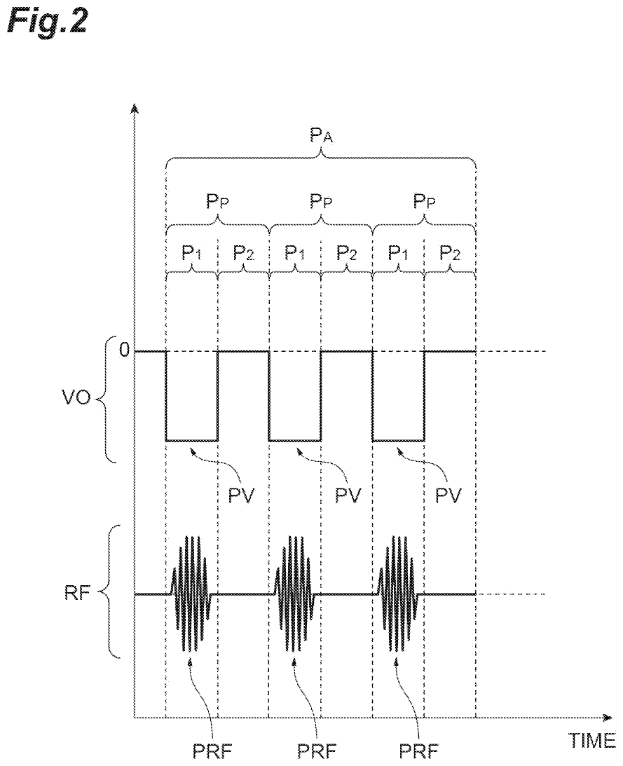

FIG. 2 is a timing chart of radio frequency power and a pulsed negative direct-current voltage according to an example. In FIG. 2, “VO” represents the output voltage of the bias power source 62, and “RF” represents the power level of the radio frequency power RF. In the example shown in FIG. 2, the first partial period P₁ is a period in which the pulsed negative direct-current voltage PV is applied to the lower electrode 18. In the example shown in FIG. 2, the second partial period P₂ is a period in which the pulsed negative direct-current voltage PV is not applied to the lower electrode 18. In the example shown in FIG. 2, one pulse PRF of the radio frequency power RF is supplied in the first partial period P₁. According to this example, ions having relatively high energy can be supplied to the substrate W.

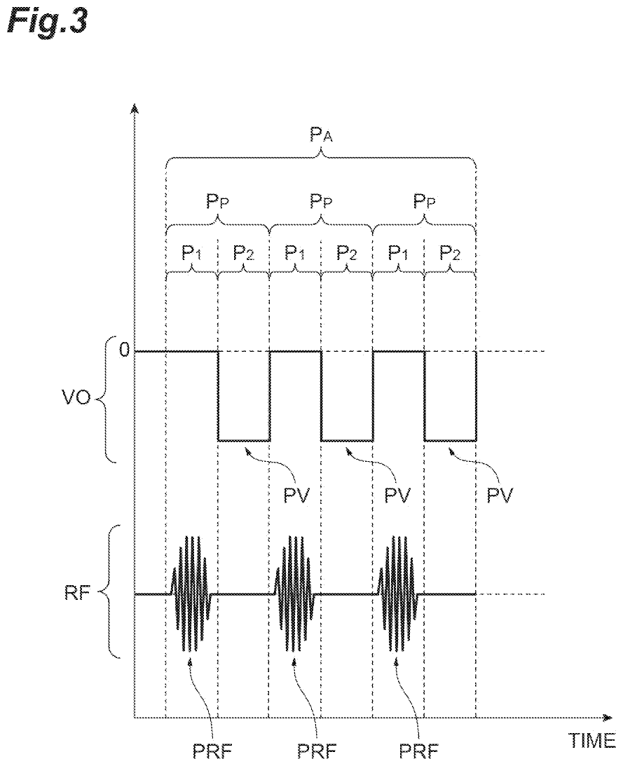

FIG. 3 is a timing chart of radio frequency power and a pulsed negative direct-current voltage according to another example. In FIG. 3, “VO” represents the output voltage of the bias power source 62, and “RF” represents the power level of the radio frequency power RF. In the example shown in FIG. 3, the first partial period P₁ is a period in which the pulsed negative direct-current voltage PV is not applied to the lower electrode 18. In the example shown in FIG. 3, the second partial period P₂ is a period in which the pulsed negative direct-current voltage PV is applied to the lower electrode 18. In the example shown in FIG. 3, one pulse PRF of the radio frequency power RF is supplied in the first partial period P₁. According to this example, ions having relatively low energy can be supplied to the substrate W.

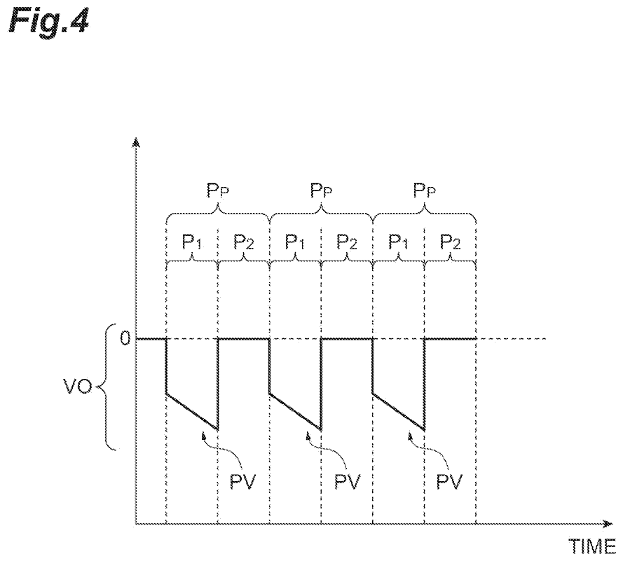

FIG. 4 is a timing chart of a pulsed negative direct-current voltage according to still another example. In FIG. 4, “VO” represents the output voltage of the bias power source 62. As shown in FIG. 4, the voltage level of the pulsed negative direct-current voltage PV may change within a period in which it is applied to the lower electrode 18. In the example shown in FIG. 4, the voltage level of the pulsed negative direct-current voltage PV decreases within the period in which it is applied to the lower electrode 18. That is, in the example shown in FIG. 4, the absolute value of the voltage level of the pulsed negative direct-current voltage PV increases within the period in which it is applied to the lower electrode 18. The pulsed negative direct-current voltage PV may be applied to the lower electrode 18 in the first partial period P₁ or may be applied to the lower electrode 18 in the second partial period P₂.

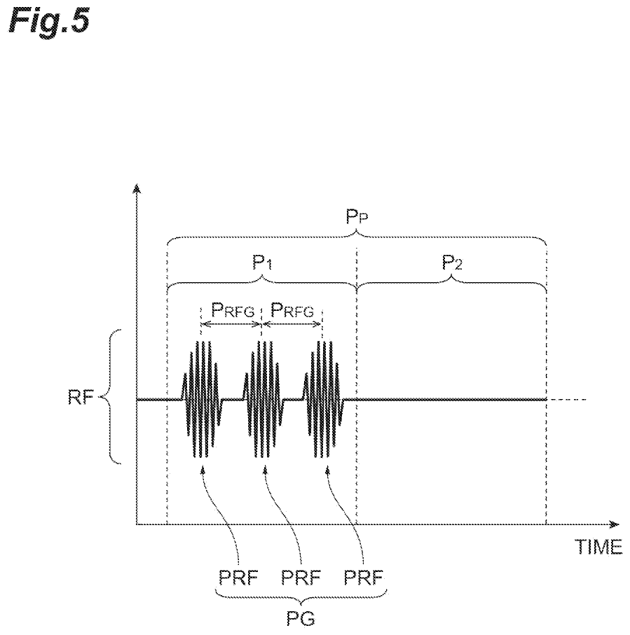

FIG. 5 is a timing chart of radio frequency power according to still another example. In FIG. 5, “RF” represents the power level of the radio frequency power RF. As shown in FIG. 5, the controller MC may control the radio frequency power source 61 to sequentially supply a plurality of pulses PRF of the radio frequency power RF in the first partial period P₁. That is, the controller MC may control the radio frequency power source 61 to supply a pulse group PG that includes the plurality of pulses PRF in the first partial period P₁. In the first partial period P₁, the pulse PRF of the radio frequency power RF may be supplied periodically. A frequency for defining a cycle P_{RFG} at which the pulse PRF of the radio frequency power RF is supplied in the first partial period P₁ may be equal to or more than twice the second frequency and equal to or less than 0.5 times the first frequency.

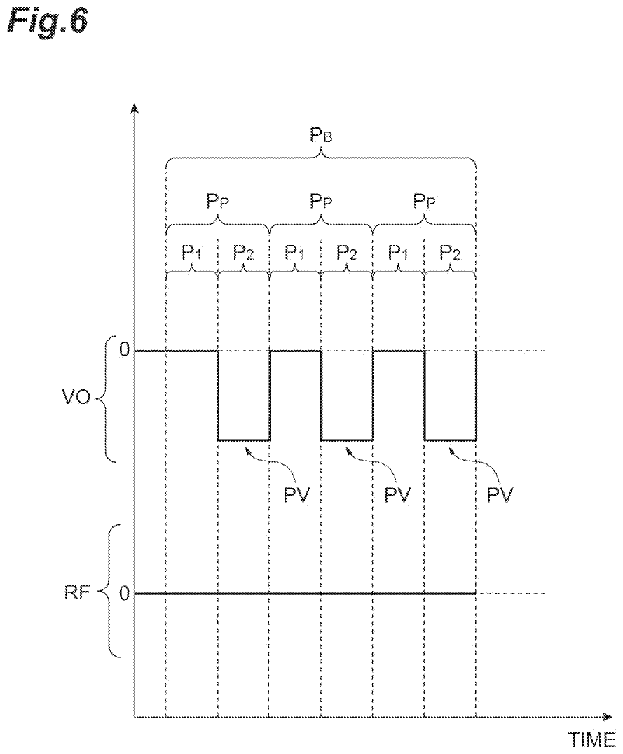

FIG. 6 is a timing chart of radio frequency power and a pulsed negative direct-current voltage according to still yet another example. In FIG. 6, “VO” represents the output voltage of the bias power source 62, and “RF” represents the power level of the radio frequency power RF. As in the example shown in FIG. 2 or 3, the plasma processing apparatus 1 periodically applies the pulsed negative direct-current voltage PV to the lower electrode 18 at the cycle P_{P} in a period P_{A}, and supplies one or more pulses PRF of the radio frequency power RF within the cycle P_{P}. As shown in FIG. 6, the controller MC may control the radio frequency power source 61 to stop the supply of the radio frequency power RF in another period P_{B}. In the period P_{B}, the controller MC may control the bias power source 62 to periodically apply the pulsed negative direct-current voltage PV to the lower electrode 18 at the cycle P_{P} in a state where the supply of the radio frequency power RF is stopped. The period P_{B} is a period having a time length longer than the time length of the cycle P_{P}. The period P_{B} may be a period in which plasma is present in the chamber 10. The period P_{B} may be, for example, a period following the period P_{A}.

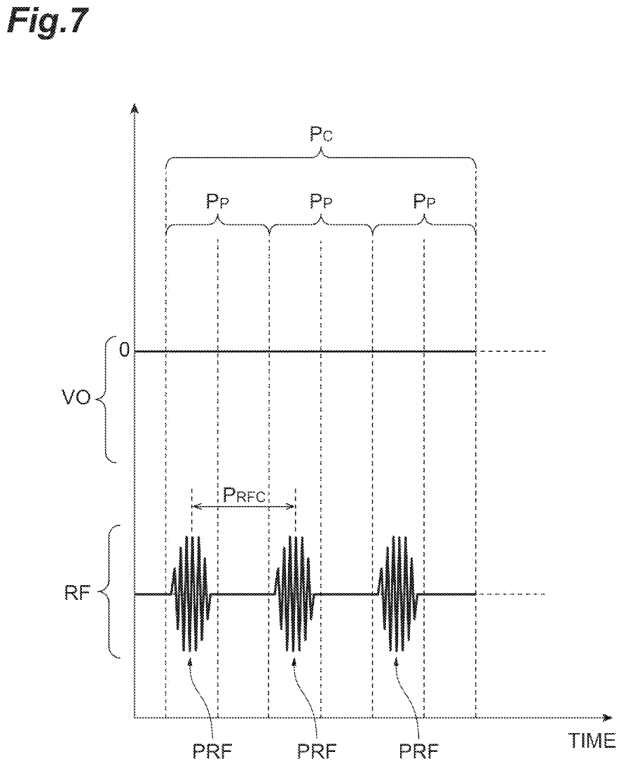

FIG. 7 is a timing chart of radio frequency power and a pulsed negative direct-current voltage according to further example. In FIG. 7, “VO” represents the output voltage of the bias power source 62, and “RF” represents the power level of the radio frequency power RF. As shown in FIG. 7, the controller MC may control the bias power source 62 to stop the application of the pulsed negative direct-current voltage PV to the lower electrode 18 in another period P_{C}. In the period P_{C}, the controller MC may control the radio frequency power source 61 to supply the radio frequency power RF in a state where the application of the pulsed negative direct-current voltage PV to the lower electrode 18 is stopped. The controller MC may control the radio frequency power source 61 to periodically supply the pulse PRF or the pulse group PG of the radio frequency power RF in the period P_{C}. A cycle P_{RFC} of the supply of the pulse PRF or the pulse group PG of the radio frequency power RF in the period P_{C} may be the same cycle as the cycle of the supply of the pulse PRF or the pulse group PG of the radio frequency power RF in the period P_{A}, that is, the cycle P_{P}. Also in the period P_{C}, a frequency for defining the cycle P_{RFG} of the supply of the pulse PRF of the radio frequency power RF forming the pulse group PG may be equal to or more than twice the second frequency and equal to or less than 0.5 times the first frequency.

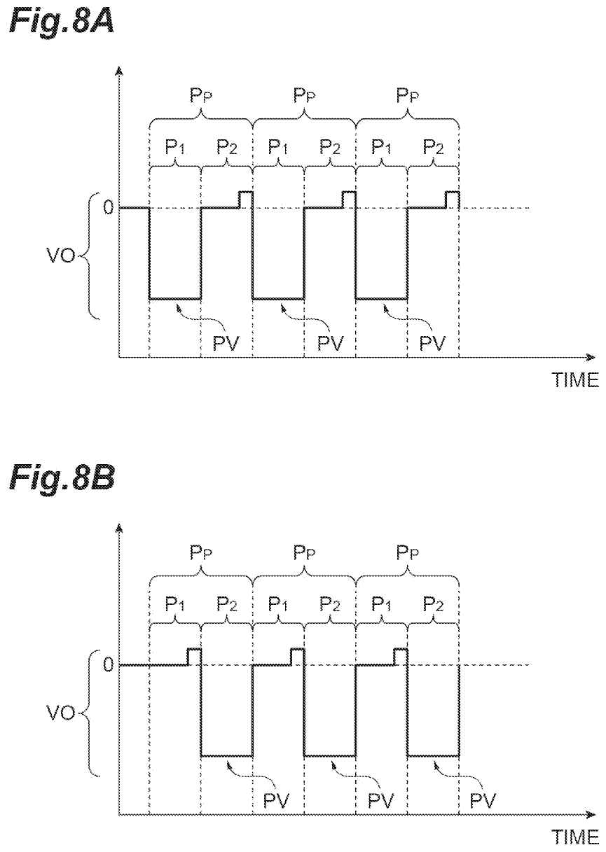

Each of FIGS. 8A and 8B is a timing chart of a pulsed negative direct-current voltage according to still further example. The output voltage VO of the bias power source 62 in the example shown in FIG. 8A is different from the output voltage VO of the bias power source 62 in the example shown in FIG. 2 in that the polarity thereof is changed to a positive polarity within the second partial period P₂ and immediately before the first partial period P₁. That is, in the example shown in FIG. 8A, a positive direct-current voltage is applied from the bias power source 62 to the lower electrode 18 within the second partial period P₂ and immediately before the first partial period P₁. In a case where the pulsed negative direct-current voltage PV is applied to the lower electrode 18 in the first partial period P₁, a positive direct-current voltage may be applied from the bias power source 62 to the lower electrode 18 in at least a part of the second partial period P₂.

The output voltage VO of the bias power source 62 in the example shown in FIG. 8B is different from the output voltage VO of the bias power source 62 in the example shown in FIG. 3 in that the polarity thereof is changed to a positive polarity within the first partial period P₁ and immediately before the second partial period P₂. That is, in the example shown in FIG. 8B, a positive direct-current voltage is applied from the bias power source 62 to the lower electrode 18 within the first partial period P₁ and immediately before the second partial period P₂. In a case where the pulsed negative direct-current voltage PV is applied to the lower electrode 18 in the second partial period P₂, a positive direct-current voltage may be applied from the bias power source 62 to the lower electrode 18 in at least a part of the first partial period P₁.

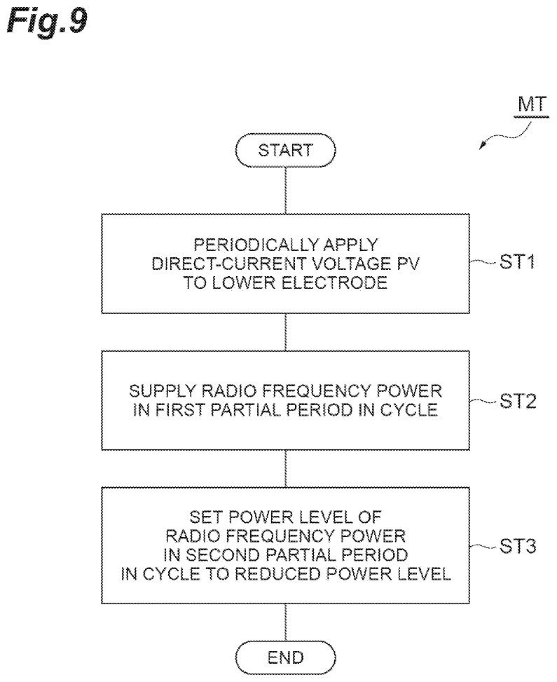

Hereinafter, FIG. 9 will be referred to. FIG. 9 is a flow chart showing a plasma processing method according to an exemplary embodiment. The plasma processing method (hereinafter referred to as a “method MT”) shown in FIG. 9 may be performed by using the plasma processing apparatus 1 described above.

The method MT is performed in a state where the substrate W is placed on the electrostatic chuck 20. The method MT is executed to perform plasma processing on the substrate W. In the method MT, a gas is supplied from the gas supply unit into the chamber 10. Then, the pressure of the gas in the chamber 10 is set to a designated pressure by the exhaust device 50.

In the method MT, step ST1 is performed. In step ST1, the pulsed negative direct-current voltage PV is periodically applied from the bias power source 62 to the lower electrode 18 at the cycle P_{P}.

Step ST2 is performed in the first partial period P₁ in the cycle P_{P}. Step ST3 is performed in the second partial period P₂ in the cycle P_{P}. The first partial period P₁ may be a period in which the pulsed negative direct-current voltage PV is applied to the lower electrode 18. The second partial period P₂ may be a period in which the pulsed negative direct-current voltage PV is not applied to the lower electrode 18. Alternatively, the first partial period P₁ may be a period in which the pulsed negative direct-current voltage PV is not applied to the lower electrode 18. The second partial period P₂ may be a period in which the pulsed negative direct-current voltage PV is applied to the lower electrode 18.

In step ST2, the radio frequency power RF is supplied from the radio frequency power source 61 for plasma generation. In the first partial period P₁, one or more pulses PRF of the radio frequency power RF may be supplied. In the first partial period P₁, a plurality of pulses PRF of the radio frequency power RF may be supplied in sequence. That is, in the first partial period P₁, the pulse group PG that includes a plurality of pulses PRF may be supplied. In the first partial period P₁, the pulse PRF of the radio frequency power RF may be supplied periodically. A frequency for defining a cycle P_{RFG} at which the pulse PRF of the radio frequency power RF is supplied in the first partial period P₁ may be equal to or more than twice the second frequency and equal to or less than 0.5 times the first frequency.

In step ST3, the power level of the radio frequency power RF in the second partial period P₂ in the cycle P_{P} is set to a power level reduced from the power level of the radio frequency power RF in the first partial period P₁. The supply of the radio frequency power RF may be stopped in the second partial period P₂.

Steps ST1 to ST3 may be performed in the period P_{A} described above. In the method MT, the pulsed negative direct-current voltage PV may be periodically applied from the bias power source 62 to the lower electrode 18 at the cycle P_{P} in a state where the supply of the radio frequency power RF from the radio frequency power source 61 is stopped, in the period P_{B} (refer to FIG. 6). As described above, the period P_{B} is a period having a time length longer than the time length of the cycle P_{P}. The period P_{B} may be a period in which plasma is present in the chamber 10. The period P_{B} may be, for example, a period following the period P_{A}.

In the method MT, the radio frequency power RF may be supplied from the radio frequency power source 61 in a state where the application of the pulsed negative direct-current voltage PV from the bias power source 62 to the lower electrode 18 is stopped, in another period P_{C} (refer to FIG. 7). In the period P_{C}, the controller MC may control the radio frequency power source 61 to supply the radio frequency power RF in a state where the application of the pulsed negative direct-current voltage PV to the lower electrode 18 is stopped. In the period P_{C}, the pulse PRF or the pulse group PG of the radio frequency power RF may be periodically supplied from the radio frequency power source 61. A cycle P_{RFC} of the supply of the pulse PRF or the pulse group PG of the radio frequency power RF in the period P_{C} may be the same cycle as the cycle of the supply of the pulse PRF or the pulse group PG of the radio frequency power RF in the period P_{A}, that is, the cycle P_{P}. Also in the period P_{C}, a frequency for defining the cycle P_{RFG} of the supply of the pulse PRF of the radio frequency power RF forming the pulse group PG may be equal to or more than twice the second frequency and equal to or less than 0.5 times the first frequency.

While various exemplary embodiments have been described above, various additions, omissions, substitutions and changes may be made without being limited to the exemplary embodiments described above. Elements of the different embodiments may be combined to form another embodiment.

The plasma processing apparatus according to another embodiment may be a capacitively coupled plasma processing apparatus different from the plasma processing apparatus 1. Further, the plasma processing apparatus according to still another embodiment may be an inductively coupled plasma processing apparatus. Further, the plasma processing apparatus according to still another embodiment may be an ECR (electron cyclotron resonance) plasma processing apparatus. Further, the plasma processing apparatus according to still another embodiment may be a plasma processing apparatus that generates plasma by using surface waves such as microwaves.

Further, the cycle P_{P} may be composed of three or more partial periods that include the first partial period P₁ and the second partial period P₂. The time lengths of the three or more partial periods in the cycle P_{P} may be the same as or different from each other. The power level of the radio frequency power RF in each of the three or more partial periods may be set to a power level different from the power levels of the radio frequency power RF in the preceding and following partial periods.

From the foregoing description, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

### REFERENCE SIGNS LIST

10: plasma processing apparatus

10: chamber;

16: substrate support

18: lower electrode

20: electrostatic chuck

61: radio frequency power source

62: bias power source

MC: controller

1. A plasma processing apparatus comprising:
a chamber;
a substrate support having a lower electrode and an electrostatic chuck provided on the lower electrode, and configured to support a substrate which is placed thereon in the chamber;
a radio frequency power source configured to generate radio frequency power which is supplied to generate plasma from a gas in the chamber, the radio frequency power having a first frequency;
a bias power source electrically connected to the lower electrode and configured to periodically apply a pulsed negative direct-current voltage to the lower electrode at a cycle that is defined by a second frequency lower than the first frequency; and
a controller configured to control the radio frequency power source,
wherein the controller controls the radio frequency power source to supply the radio frequency power in a first partial period in the cycle and set a power level of the radio frequency power in a second partial period in the cycle to a power level reduced from a power level of the radio frequency power in the first partial period.

2. The plasma processing apparatus according to claim 1, wherein the first partial period is a period in which the pulsed negative direct-current voltage is applied to the lower electrode, and
the second partial period is a period in which the pulsed negative direct-current voltage is not applied to the lower electrode.

3. The plasma processing apparatus according to claim 1, wherein the first partial period is a period in which the pulsed negative direct-current voltage is not applied to the lower electrode, and
the second partial period is a period in which the pulsed negative direct-current voltage is applied to the lower electrode.

4. The plasma processing apparatus according to claim 1, wherein the controller controls the radio frequency power source to stop supply of the radio frequency power in the second partial period.

5. The plasma processing apparatus according to claim 1, wherein the controller controls the radio frequency power source to periodically supply a pulse of the radio frequency power in the first partial period.

6. The plasma processing apparatus according to claim 5, wherein a frequency for defining a cycle at which the pulse of the radio frequency power is supplied in the first partial period is equal to or more than twice the second frequency and equal to or less than 0.5 times the first frequency.

7. A plasma processing method using a plasma processing apparatus,
the plasma processing apparatus including
a chamber,
a substrate support having a lower electrode and an electrostatic chuck provided on the lower electrode, and configured to support a substrate which is placed thereon in the chamber,
a radio frequency power source configured to generate radio frequency power which is supplied to generate a plasma from a gas in the chamber, the radio frequency power having a first frequency, and
a bias power source electrically connected to the lower electrode,
the plasma processing method being executed to perform plasma processing on a substrate in a state where the substrate is placed on the electrostatic chuck, and comprising:
periodically applying a pulsed negative direct-current voltage from the bias power source to the lower electrode at a cycle that is defined by a second frequency lower than the first frequency;
supplying the radio frequency power from the radio frequency power source in a first partial period in the cycle; and
setting a power level of the radio frequency power in a second partial period in the cycle to a power level reduced from a power level of the radio frequency power in the first partial period.

8. The plasma processing method according to claim 7, wherein the first partial period is a period in which the pulsed negative direct-current voltage is applied to the lower electrode, and
the second partial period is a period in which the pulsed negative direct-current voltage is not applied to the lower electrode.

9. The plasma processing method according to claim 7, wherein the first partial period is a period in which the pulsed negative direct-current voltage is not applied to the lower electrode, and
the second partial period is a period in which the pulsed negative direct-current voltage is applied to the lower electrode.

10. The plasma processing method according to claim 7, wherein supply of the radio frequency power is stopped in the second partial period.

11. The plasma processing method according to claim 7, wherein a pulse of the radio frequency power is periodically supplied from the radio frequency power source in the first partial period.

12. The plasma processing method according to claim 11, wherein a frequency for defining a cycle at which the pulse of the radio frequency power is supplied in the first partial period is equal to or more than twice the second frequency and equal to or less than 0.5 times the first frequency.

13. The plasma processing method according to claim 7, further comprising:
periodically applying the pulsed negative direct-current voltage from the bias power source to the lower electrode at the cycle that is defined by the second frequency, in a state where supply of the radio frequency power from the radio frequency power source is stopped, in a period in which plasma is present in the chamber and which has a time length longer than a time length of the cycle that is defined by the second frequency.

14. The plasma processing method according to claim 7, further comprising:
supplying the radio frequency power from the radio frequency power source in a state where application of the pulsed negative direct-current voltage from the bias power source to the lower electrode is stopped, in a period having a time length longer than a time length of the cycle that is defined by the second frequency.
